(19) United States
(12) Patent Application Publication
(10) Pub. No.: US 2007/0082499 A1
(43) Pub. Date: Apr. 12, 2007

(54) Photoresist coating apparatus, medium, and method efficiently spraying photoresist

(75) Inventors: Chang Hoon Jung, Seoul (KR); Tae Gyu Kim, Hwaseong-si (KR); Jin Sung Lee, Seoul (KR); June Mo Koo, Yongin-si (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-si (KR)

(21) Appl. No.: 11/489,465

(22) Filed: Jul. 20, 2006

(30) Foreign Application Priority Data
Oct. 11, 2005 (KR) 10-2005-0095643

(51) Int. Cl. H01L 21/31; H01L 21/469

(52) U.S. Cl. 438/758; 438/760

(57) ABSTRACT

A photoresist coating apparatus, medium, and method for efficiently spraying a liquid photoresist to maintain an atmosphere of ionized solvent vapor between a substrate and a spray nozzle of an upper portion by using a vapor inducing pipe supplying ionized solvent vapor, with the atmosphere being maintained by differently biasing a lower portion supporting the substrate and a plate of the upper portion. Photoresist can be evenly coated over the entire surface of the substrate while reducing the loss of sprayed photoresist droplets.

### CROSS-REFERENCE TO RELATED APPLICATIONS

This application claims the priority benefit of Korean Patent Application No.10-2005-95643, filed on Oct. 11, 2005, in the Korean Intellectual Property Office, the disclosure of which is incorporated herein by reference.

### BACKGROUND OF THE INVENTION

1. Field of the Invention

Embodiments of the present invention relate at least to a photoresist coating apparatus, medium, and method, and more particularly, to an apparatus, medium, and method for dispersing photoresist while reducing a loss in photoresist droplets vaporized or lost by down flow, for example.

2. Description of the Related Art

Photoresist coating is a process which has been widely used in semiconductors, LCDs (Liquid Crystal Displays), MEMS (microelectromechanical systems), for example. For patterning an integrated circuit device, such as pattering metal or generating via holes, a liquid photoresist may be evenly coated on a surface, such as a semiconductor wafer or a glass substrate. Thereafter, an exposed photoresist portion may be removed through exposing and developing processes to remove some of the applied photoresist.

FIG. 1 illustrates a conventional photoresist coating apparatus 100 that may include a spray nozzle 110 for spraying a liquid photoresist on a substrate 120, such as a wafer, placed on a holder 130. The holder 130 may be used to prevent the wafer from wobbling during the patterning process. In this instance, photoresist droplets may be evenly spread on the substrate 120 to coat the entire surface of the substrate 120. After this, a desired pattern may be generated on the substrate 120, e.g., through any of thermal, exposing, and developing processes.

The spray nozzle may be an ultrasonic spray nozzle, e.g., an orifice tube and the like may be used as the spray nozzle 110 of FIG. 1. The spray method may spray a large amount of photoresist over the entire surface of a wafer in a short amount of time.

However, in such a conventional photoresist coating operation, photoresist droplets may be caused to drop beyond the substrate 120 along a down flow and may vaporize before minute photoresist droplets reach the surface of the substrate 120. Here, the loss of liquid photoresist increases manufacturing costs.

In such a conventional system, Japanese Patent Publication No. 8-153669 discusses a photoresist coating method using an electro spray to improve the possibility photoresist droplets sprayed from a spray nozzle to attach to a wafer. The method uses an electric field formed between the wafer and the spray nozzle according to a high voltage supplied to the spray nozzle. However, even in this conventional method, there still is an insufficient coating atmosphere created between the spray nozzle and the wafer. Accordingly, minute photoresist droplets may still vaporize. In addition, the amount of photoresist sprayed to the wafer may not be easily controlled. Further, since only an infinitesimal amount of photoresist is sprayed, photoresist may not be quickly or evenly coated on the entire surface of a wafer.

### SUMMARY OF THE INVENTION

To solve the aforementioned problems, embodiments of the present invention include a photoresist coating apparatus, medium, and method that can maintain an appropriate coating atmosphere between a spray nozzle and a substrate, and prevent photoresist droplets from vaporizing or being lost because of down flow, thereby effectively using liquid photoresist.

Embodiments of the present invention also include a photoresist coating apparatus, medium, and method that can form an atmosphere of ionized solvent vapor between a spray nozzle and a substrate and prevent vaporization or loss of photoresist droplets.

To achieve the above and/or other aspects and advantages, embodiments of the present invention include a photoresist coating apparatus, including at least one photoresist dispenser to dispense a photoresist onto a substrate, and at least one vapor dispenser to dispense ionized vapor to the substrate, wherein the dispensed photoresist is confined while being dispensed to the surface of the substrate by the dispensed ionized vapor, with the dispensed ionized vapor being guided at least by an electric field.

The one photoresist dispenser may be within a vapor inducing pipe.

In addition, the apparatus may include a holder to hold the substrate and a plate separated from the holder by a certain distance. The plate may include a plurality of holes. Further, the plurality of holes of the plate may permit down flow blowing onto one side of the plate to pass through the holes toward the holder.

The electric field may be generated by the holder and the plate being biased to different voltages. In addition, the holder may be biased to a voltage higher than a voltage of the plate, and the ionized vapor may be charged to have a single polarity. Further, the apparatus may include a control electrode provided around the holder and separated from the holder by a certain distance, with the control electrode being biased to a voltage between the bias voltage of the holder and bias voltage of the plate.

In the apparatus, the ionized vapor may be an ionized solvent vapor. In addition, a unipolar charger may be used to generate the ionized vapor.

The at least one photoresist dispenser may include two or more spray nozzles, and each of the spray nozzles may be configured to spray liquid photoresist on an area of the substrate to coat an entire surface of the substrate with the liquid photoresist.

The at least one photoresist dispenser may further be one spray nozzle, with the spray nozzle being moved by a transfer unit over the substrate. A rotation unit may further be used to rotate the substrate during a photoresist dispensing operation.

The apparatus may include a control electrode provided laterally next to the substrate, with the control electrode being biased to a voltage between bias voltages generating the electric field.

To achieve the above and/or other aspects and advantages, embodiments of the present invention include a photoresist coating method, including dispersing a photoresist to a substrate, and forming an atmosphere of ionized vapor between a vapor dispenser and the substrate, wherein the ionized vapor atmosphere confines lateral dispersion of the photoresist on the substrate.

The forming of the atmosphere the dispensed ionized vapor may be guided at least by an electric field. In addition, the method may include generating an electric field to guide the dispensed ionized vapor.

The generating of the electric field may be generated between a holder and a plate having at least one spray nozzle to perform the photoresist dispersion, by the holder and plate being biased at different voltages.

The forming of the atmosphere of the ionized vapor may include biasing a base below the substrate and an upper portion to different voltages, supplying a down flow between the upper portion and towards the base, and generating the ionized vapor via a vapor inducing supply.

Here, the base may be biased to a higher voltage than a voltage of the upper portion, and the ionized vapor may be charged to have a single polarity.

In the method, the dispersing of the photoresist may be performed by two or more separate photoresist dispensers, and each of the photoresist dispensers may dispense liquid photoresist over areas of the substrate to coat an entire surface of the substrate with the liquid photoresist.

The dispersing of the photoresist to the substrate may further be performed by at least one photoresist dispenser moved over the substrate. The method may further include rotating the substrate during dispersion of photoresist on the substrate. In addition, the dispersing of the photoresist to the substrate may be performed by a single photoresist dispenser.

The method may include guiding the ionized vapor between an edge portion of the substrate and a control electrode positioned laterally next to the substrate. In addition, the method may further include biasing the control electrode to a voltage between bias voltages generating the electric field.

To achieve the above and/or other aspects and advantages, embodiments of the present invention include at least one medium including computer readable code to implement embodiments of the present invention.

Additional aspects and/or advantages of the invention will be set forth in part in the description which follows and, in part, will be apparent from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 illustrates a conventional photoresist coating apparatus;

FIG. 2 illustrates a photoresist coating apparatus, according to an embodiment of the present invention;

FIG. 3 is a top view illustration of a plate, such as that of FIG. 2, according to an embodiment of the present invention;

FIG. 4 illustrates a photoresist coating apparatus, according to another embodiment of the present invention;

FIG. 5 illustrates a coating area on a substrate created by the plurality of spray nozzles of FIG. 4;

FIG. 6 illustrates a photoresist coating apparatus, according to still another embodiment of the present invention;

FIG. 7 illustrates a coating area on a substrate created by the spray nozzle of FIG. 6;

FIG. 8 illustrates a photoresist coating apparatus, according to yet another embodiment of the present invention; and

FIG. 9 illustrates control electrodes provided around a holder, such as the holder of FIG. 8, according to an embodiment of the present invention.

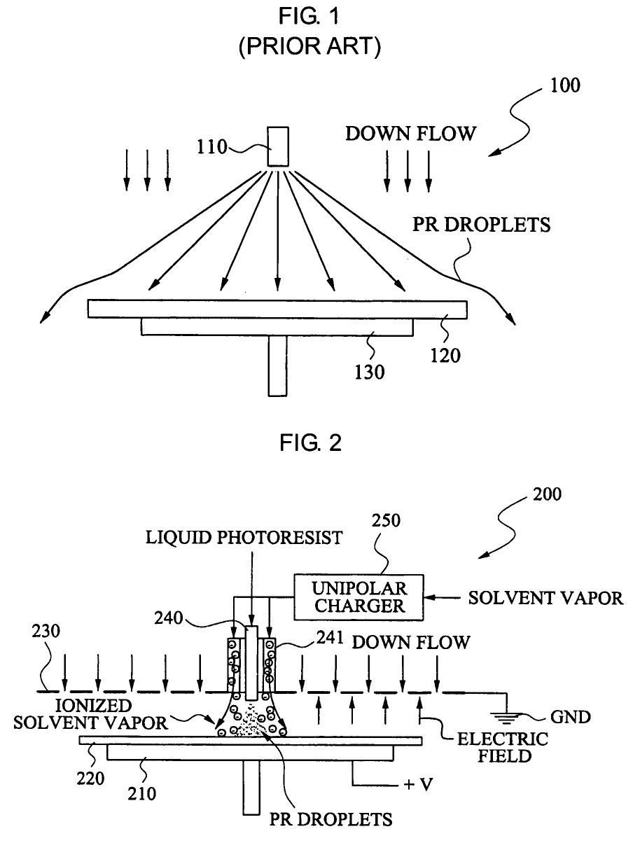

### DETAILED DESCRIPTION OF THE PREFERRED EMBODIMENTS

Reference will now be made in detail to embodiments of the present invention, examples of which are illustrated in the accompanying drawings, wherein like reference numerals refer to the like elements throughout. Embodiments are described below to explain the present invention by referring to the figures.

FIG. 2 illustrates a photoresist coating apparatus 200, according to an embodiment of the present invention. Referring to FIG. 2, the photoresist coating apparatus 200 may include a holder 210, a plate 230, a vapor inducing pipe 241 to supply an ionized solvent vapor, a spray nozzle 240, and a unipolar charger 250, for example. The vapor inducing pipe 241 corresponds to a vapor dispenser. The spray nozzle 240 corresponds to a photoresist dispenser.

The holder 210 may be used to hold a substrate 220, such as a semiconductor wafer or a glass substrate, in a photoresist coating process. The substrate 220 may be fixed, e.g., using a vacuum pump (not illustrated) so as to not wobble, while the photoresist coating process is proceeding. The vacuum pump could be connected to the holder 210, for example. Further, in such a coating process, the holder 210 may be biased to a voltage, such as +V or −V, based on the polarity of the ionized solvent vapor.

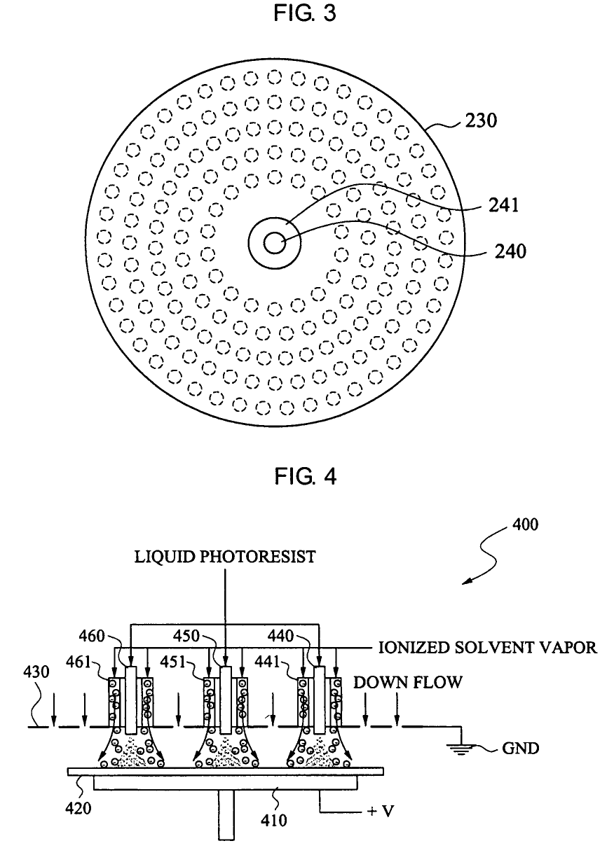

The plate 230 may be a metal plate, for example, having a plurality of holes, as shown in FIG. 3, noting that alternative embodiments are equally available. The plate 230 may be separated from the holder 210 by a certain distance. Here, the holes formed in the plate 230 may permit down flow from above the plate 230 to pass through the holes towards the holder 210. In an embodiment, the photoresist coating apparatus 200 may be provided in a closed space of a clean room, for example, where down flow exists. The photoresist coating apparatus 200 may also be installed in an open space of a clean room where down flow exists. The down flow existing in the clean room or in the closed space provided with the photoresist coating apparatus 200 can force sprayed photoresist droplets to descend downward, with directional properties, to prevent random movement of the sprayed photoresist droplets.

In an embodiment of the present invention, the plate 230 may be grounded. However, embodiments of the present invention are is not limited thereto, as the plate 230 may alternatively be biased to another voltage to form an electric field between the holder 210 and the plate 230. Namely, the plate 230 may be biased to lower or higher voltages than a voltage such as +V or −V biasing the holder 210, depending on the desired direction of the electric field formed between the holder 210 and the plate 230.

According to an embodiment of the present invention, the spray nozzle 240 is within the vapor inducing pipe 241 to supply the ionized solvent vapor. The vapor inducing pipe 241 and the spray nozzle 240 may be integrated and provided in the center of the plate 230, as illustrated in FIG. 3, for example.

The unipolar charger 250 can be used to ionize the solvent vapor and supply the ionized solvent vapor to the vapor inducing pipe 241. Here, the solvent vapor may be selected from any appropriate material which may not substantially affect photosensitivity, for example, and sprayed from the spray nozzle 240 and coated on the substrate 220. The solvent vapor may be ionized by using various methods, e.g., the solvent vapor may be ionized by a corona discharge. As another example, the solvent vapor may be combined with an electron coming from a radioactive source and ionized, or the solvent vapor may be ionized by using a method of colliding solvent vapor with a high energy photon via a photon ionizer, noting that alternative embodiments are equally available.

In the photoresist coating process, the atmosphere of ionized solvent vapor may be formed between the spray nozzle 240 and the holder 210 holding the substrate 220. Namely, in an example, if the holder 210 is biased to a voltage of 300 volts and the plate 230 is grounded, an electric field can be formed from the holder 210 towards the plate 230. In this case, the down flow passes through the holes of the plate 230 towards the holder 210 while the ionized solvent vapor is supplied via the vapor inducing pipe 241, having the spray nozzle 240 within it, for example. Accordingly, an appropriate atmosphere for photoresist coating can be fostered between the spray nozzle 240 and the holder 210 holding the substrate 220.

When the ionized solvent vapor is charged by a cathode via the unipolar charger 250, the cathodic solvent vapor is directed towards the substrate 220 by the electric field between the holder 210 towards the plate 230. In the above-described atmosphere, the spray nozzle 240 may spray a liquid photoresist towards the substrate 220 such that photoresist droplets that are spread from the spray nozzle 240 attach to the substrate 220 within the atmosphere of the ionized solvent vapor.

Here, using this ionized solvent vapor atmosphere, the vaporization of the photoresist droplets and the loss thereof can be reduced. As the photoresist droplets may spread in all directions, the photoresist droplets may collide with the cathodic solvent vapor. In this case, the photoresist droplets may be charged to have the same electric charge, by the collision, or may be coupled together with the cathodic solvent vapor. Accordingly, it is also highly possible that the photoresist droplets may also be directed toward the substrate 220 by the electric field. This additional benefit may contribute to a further reducing of photoresist droplets dropping beyond the edges of the substrate 220. Accordingly, with embodiments of the present invention, loss of photoresist droplets by down flow may be reduced.

When the size of a semiconductor wafer or a glass substrate placed on the holder 210 is large, a single spray nozzle 240, such as that illustrated in FIG. 2, may not be able to sufficiently perform photoresist coating over the entire surface of the wafer. In this case, as illustrated in FIGS. 4 and 6, additional embodiments of the present invention may further overcome this potential problem.

As illustrated in FIG. 4, a photoresist coating apparatus 400 may include a holder 410, holding a substrate 420, a plate 430, vapor inducing pipes 441, 451, and 461 to supply of the ionized solvent vapor, and spray nozzles 440, 450, and 460 to supply the photoresist. To supply ionized solvent vapor via the vapor inducing pipes 441, 451, and 461, the photoresist coating apparatus 400 may also include a unipolar charger (not illustrated), similar to that shown in FIG. 2. Here, one or more spray nozzles 440, 450, and 460 may be provided.

An operation of the photoresist coating apparatus 400 may be similar to the photoresist coating apparatus 200 in FIG. 2, with the spray nozzles 440, 450, and 460 respectively being included within the vapor inducing pipes 441, 451, and 461 to supply the ionized solvent vapor. Each of the spray nozzles 440, 450, and 460 and each of the vapor inducing pipes 441, 451, and 461 may be positioned over predetermined portions of the plate 430, for example.

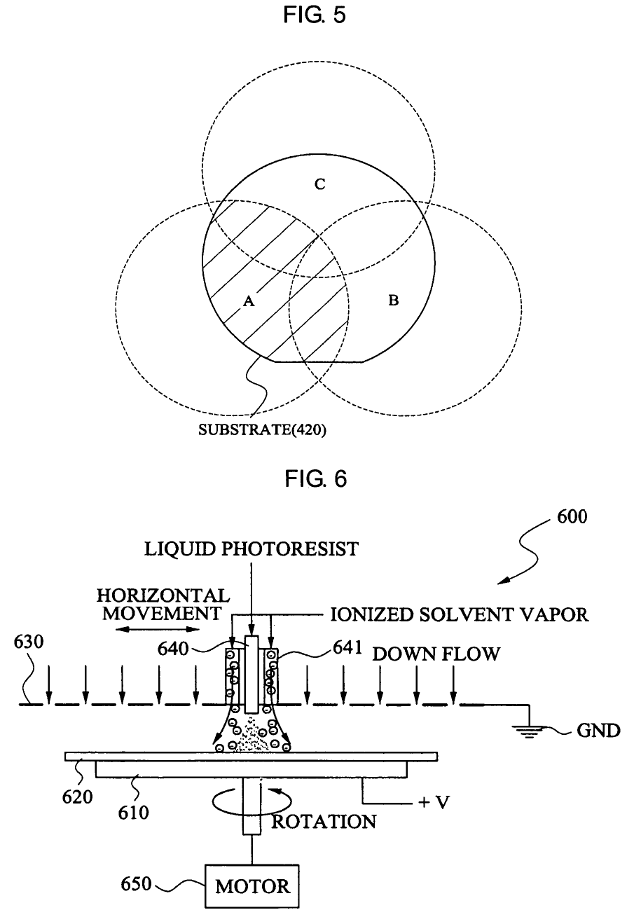

In the photoresist coating process, each of the spray nozzles 440, 450, and 460 may thus coat photoresist over the entire surface of the substrate 420, e.g., using a method of spraying a liquid photoresist over an area of the substrate 420 as illustrated in FIG. 5. Namely, the first spray nozzle 440 may coat photoresist in area A of the substrate 420, the second spray nozzle 450 may coat photoresist in area B of the substrate 420, and the third spray nozzle may coat photoresist in area C of the substrate 420.

In this instance, it has been assumed that there are three spray nozzles 440, 450, and 460. However, embodiments of the present invention are not limited thereto, there may only need to be a sufficient number of spray nozzles to cover the entire surface of the substrate 420.

Similarly, as illustrated in FIG. 6, photoresist coating apparatus 600 may include a holder 610, holding the substrate 620, a plate 630, a vapor inducing pipe 641 to supply the ionized solvent vapor, a spray nozzle 640 and a motor 650. The photoresist coating apparatus 600 may further include a unipolar charger (not illustrated), such as that illustrated in FIG. 2, in order to supply the ionized solvent vapor to the vapor inducing pipe 641.

Again, the operation of the photoresist coating apparatus 600 may be similar to the photoresist coating apparatus 200 in FIG. 2, for example. As illustrated, the spray nozzle 640 and the plate 630 may be horizontally moved by a transfer unit (not illustrated) to permit photoresist coating to be performed over the entire surface of the substrate 620. The motor 650 may rotate a rotation axle connected to the holder 610, thereby rotating the holder 610 holding the substrate 620.

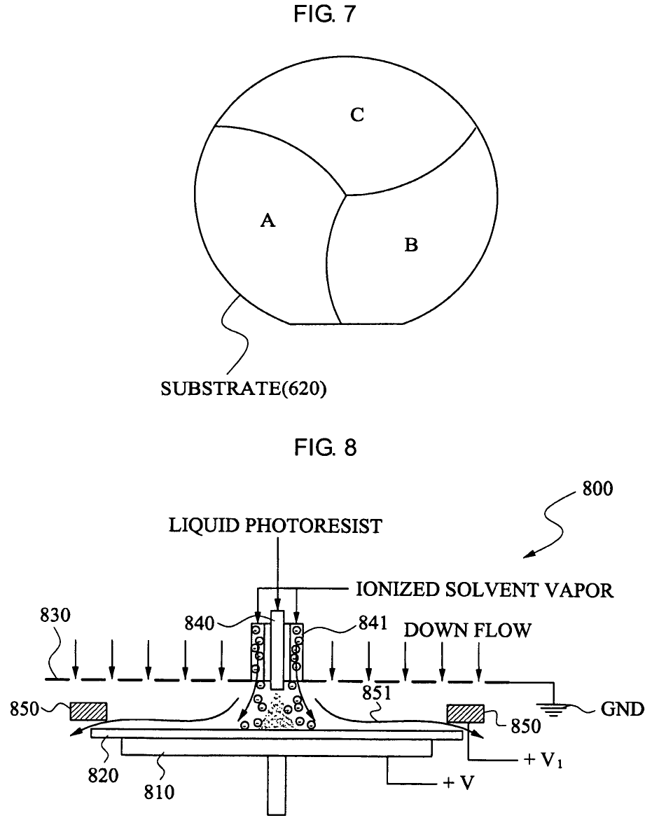

In this case, as illustrated in FIG. 7, photoresist may be coated over the entire surface of the substrate 620. Namely, while rotating the holder 610, the spray nozzle 640 may spray a liquid photoresist while the spray nozzle 640 and the plate 630 are being transferred in one (or more) direction, e.g., to the right, resulting in area A of the substrate 620 being coated with photoresist. Similarly, while the spray nozzle 640 and the plate 630 are being transferred in another direction, e.g., to the left, area B of the substrate 620 is coated with photoresist. Lastly, while the spray nozzle 640 and the plate 630 are being transferred again in a different direction, e.g., to the right, area C of the substrate 620 is coated with photoresist. Again, differing embodiments are equally available.

In the above example, if it is possible to cover the entire surface of the substrate 620, the spray nozzle 640 and the plate 630 may be transferred in only one direction without a back-and-forth motion or may be further horizontally moved as required.

FIG. 8 illustrates a photoresist coating apparatus 800, according to yet another embodiment of the present invention. Referring to FIG. 8, the photoresist coating apparatus 800 may include a holder 810, holding a substrate 820, a plate 830, a vapor inducing pipe 841 to supply the ionized solvent vapor, a spray nozzle 840, and a control electrode 850. The photoresist coating apparatus 800 may further include a unipolar charger (not illustrated), such as that illustrated in FIG. 2, to supply ionized solvent vapor to the vapor inducing pipe 841.

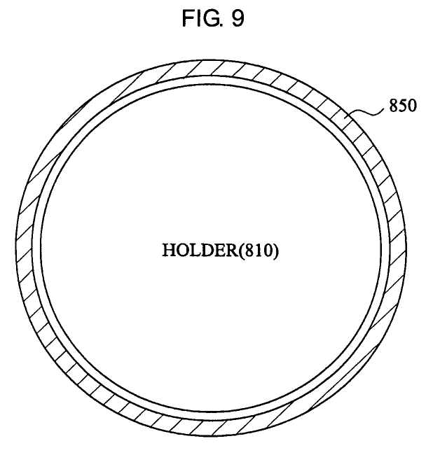

The operation of the photoresist coating apparatus 800 may be similar to the photoresist coating apparatus 200 in FIG. 2, for example. In this case, as illustrated in FIG. 9, the photoresist coating apparatus 800 may include the control electrodes 850 provided around the holder 810, separated from the holder 810 by a certain distance.

As illustrated in FIG. 8, the electric field formed between the holder 810 and the control electrode 850 induces cathodic solvent vapor 851 to be gathered between an edge portion of the substrate 820 and the control electrode 850. For this, the control electrode 850 may be biased to a voltage between the biased voltages of the holder 810 and the plate 830. As only an example, when the holder 810 is 300 volts and the plate 830 is grounded, the control electrode 850 may be biased to 200 volts, noting that alternative embodiments are equally available.

In such a photoresist coating process, the ionized solvent vapor 851 induced between the control electrode 850 and the edge portion of the substrate 820 may force photoresist droplets to move in the direction toward the edge portion of the substrate 820. When the photoresist droplets are being spread in all directions, photoresist droplets reaching the edge portion of the substrate 820 are charged because of collision with the cathodic solvent vapor 851 or attached thereto. Accordingly, the photoresist droplets may be attached to the substrate 820 rather than passing beyond the edge of substrate 820, as dictated by the electric field formed in the edge portion of the substrate 820. Accordingly, an amount of photoresist droplets vaporizing, or not attaching to the substrate 820 and lost by flowing along the down flow, can be reduced.

A structure in which the control electrodes 850 are provided around the holder 810, e.g., as illustrated in FIG. 8, is also applicable to a structure of using a plurality of spray nozzles 440, 450, and 460, such as illustrated in FIG. 4, or to a structure of the rotating holder 610 and horizontally moving spray nozzle 640, such as illustrated in FIG. 6.

As described above, embodiments of the present invention can maintain an atmosphere of ionized solvent vapor between a substrate biased to a certain voltage, and a spray nozzle(s), by using a differently biased plate and corresponding the vapor inducing pipes supplying ionized solvent vapor. Such a photoresist coating apparatus may reduce the loss of sprayed photoresist droplets and permit photoresist to be evenly coated over the entire surface of the substrate.

In addition to the above described embodiments, embodiments of the present invention can also be implemented through computer readable code/instructions in/on at least one medium, e.g., a computer readable medium or media. The medium can correspond to any medium/media permitting the storing and/or transmission of the computer readable code, for example.

The computer readable code can be recorded/transferred on a medium in a variety of ways, with examples of the medium including magnetic storage media (e.g., ROM, floppy disks, hard disks, etc.), optical recording media (e.g., CD-ROMs, or DVDs), and storage/transmission media such as carrier waves, as well as through the Internet, for example. The media may also be a distributed network, so that the computer readable code is stored/transferred and executed in a distributed fashion.

Thus, as described above, a photoresist coating apparatus, medium, and method, according to differing embodiments of the same, permit the prevention of photoresist droplets from vaporizing or being lost from an atmosphere of ionized solvent vapor formed between a spray nozzle and a holder holding a plate. Namely, a photoresist coating apparatus, medium, and method, according to embodiments of the present invention, may improve a possibility that photoresist droplets may attach to the substrate. Accordingly, it is possible to save liquid photoresist and decrease manufacturing costs in manufacturing semiconductor circuits and the like.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A photoresist coating apparatus, comprising:
at least one photoresist dispenser to dispense a photoresist onto a substrate; and
at least one vapor dispenser to dispense ionized vapor to the substrate,
wherein the dispensed photoresist is confined while being dispensed to the surface of the substrate by the dispensed ionized vapor, with the dispensed ionized vapor being guided at least by an electric field.

2. The apparatus of claim 1, wherein the one photoresist dispenser is within a vapor inducing pipe.

3. The apparatus of claim 1, further comprising a holder to hold the substrate and a plate separated from the holder by a certain distance.

4. The apparatus of claim 3, wherein the plate comprises a plurality of holes.

5. The apparatus of claim 4, wherein the plurality of holes of the plate permit down flow blowing onto one side of the plate to pass through the holes toward the holder.

6. The apparatus of claim 3, wherein the electric field is generated by the holder and the plate being biased to different voltages.

7. The apparatus of claim 6, wherein
the holder is biased to a voltage higher than a voltage of the plate, and
the ionized vapor is charged to have a single polarity.

8. The apparatus of claim 6, further comprising:
a control electrode provided around the holder and separated from the holder by a certain distance.

9. The apparatus of claim 8, wherein the control electrode is biased to a voltage between the bias voltage of the holder and bias voltage of the plate.

10. The apparatus of claim 1, wherein the ionized vapor is an ionized solvent vapor.

11. The apparatus of claim 1, further comprising a unipolar charger to generate the ionized vapor.

12. The apparatus of claim 1, wherein
the at least one photoresist dispenser comprises two or more spray nozzles, and
each of the spray nozzles is configured to spray liquid photoresist on an area of the substrate to coat an entire surface of the substrate with the liquid photoresist.

13. The apparatus of claim 1, wherein
the at least one photoresist dispenser comprises one spray nozzle, with the spray nozzle being moved by a transfer unit over the substrate.

14. The apparatus of claim 13, further comprising a rotation unit to rotate the substrate during a photoresist dispensing operation.

15. The apparatus of claim 1, further comprising:
a control electrode provided laterally next to the substrate, with the control electrode being biased to a voltage between bias voltages generating the electric field.

16. A photoresist coating method, comprising:
dispersing a photoresist to a substrate; and
forming an atmosphere of ionized vapor between a vapor dispenser and the substrate,
wherein the ionized vapor atmosphere confines lateral dispersion of the photoresist on the substrate.

17. The method of claim 16, wherein in the forming of the atmosphere the dispensed ionized vapor is guided at least by an electric field.

18. The method of claim 16, further comprising generating an electric field to guide the dispensed ionized vapor.

19. The method of claim 18, wherein the generating of the electric field is generated between a holder and a plate comprising at least one spray nozzle to perform the photoresist dispersion, by the holder and plate being biased at different voltages.

20. The method of claim 16, wherein the forming of the atmosphere of the ionized vapor comprises:
biasing a base below the substrate and an upper portion to different voltages;
supplying a down flow between the upper portion and towards the base; and
generating the ionized vapor via a vapor inducing supply.

21. The method of claim 20, wherein
the base is biased to a higher voltage than a voltage of the upper portion, and
the ionized vapor is charged to have a single polarity.

22. The method of claim 16, wherein
the dispersing of the photoresist is performed by two or more separate photoresist dispensers, and
each of the photoresist dispensers dispenses liquid photoresist over areas of the substrate to coat an entire surface of the substrate with the liquid photoresist.

23. The method of claim 16, wherein the dispersing of the photoresist to the substrate is performed by at least one photoresist dispenser moved over the substrate.

24. The method of claim 23, further comprising rotating the substrate during dispersion of photoresist on the substrate.

25. The method of claim 23, wherein the dispersing of the photoresist to the substrate is performed by a single photoresist dispenser.

26. The method of claim 16, further comprising:
guiding the ionized vapor between an edge portion of the substrate and a control electrode positioned laterally next to the substrate.

27. The method of claim 26, further comprising biasing the control electrode to a voltage between bias voltages generating the electric field.

28. At least one medium comprising computer readable code to implement the method of claim 16.

29. At least one medium comprising computer readable code to implement the method of claim 18.
